(19) United States
(12) Patent Application Publication
(10) Pub. No.: US 2008/0078505 A1
(43) Pub. Date: Apr. 3, 2008

(54) PLASMA ETCHING APPARATUS AND PLASMA ETCHING METHOD

(76) Inventors: Naoyuki Kofuji, Tokyo (JP); Hiroshi Akiyama, Kudamatsu-shi (JP); Kouhei Satou, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/670,048

(22) Filed: Feb. 1, 2007

(30) Foreign Application Priority Data
Oct. 3, 2006 (JP) 2006-271362

(51) Int. Cl. H01L 21/306

(52) U.S. Cl. 156/345.33

(57) ABSTRACT

The invention provides a method for overcoming the drawbacks of deteriorated throughput, deteriorated reproducibility and plasma discharge instability when continuous discharge is performed during multiple steps of plasma etching. The present invention provides a gas switching method for switching from gas supply source 101 to gas supply source 111, wherein the gas supply source 101 is switched to gas supply source 111 by opening a valve 114 in advance, setting a flow rate of MFC 112 to a flow rate used in the subsequent step, letting the gas supply source 111 to flow toward an exhaust means 5, and closing the valve 114 simultaneously when opening the valve 113, wherein a volume V1 of an area of a gas pipe 115 surrounded by the valve 113, the valve 114 and the MFC 112 is set sufficiently smaller than a volume Vo from the shower plate to the valve 113 including a gas reservoir 10 and a processing gas line 8. The present arrangement enables to prevent the occurrence of pressure undershoot and to solve the problem of discharge instability.

The present application is based on and claims priority of Japanese patent application No. 2006-271362 filed on Oct. 3, 2006, the entire contents of which are hereby incorporated by reference.

### BACKGROUND OF THE INVENTION

1. Field of the Invention

The present invention relates to a plasma etching apparatus for processing semiconductor substrates such as semiconductor wafers, and a plasma etching method utilizing the apparatus.

2. Description of the Related Art

We will describe the transition regarding the art of plasma etching used for processing gates in semiconductor devices. Until the early 1990s, a single layer Poly-Si film was used for gate electrodes. Therefore, the gates were mainly processed under a single etching condition. In the late 1990s, when gates having a multi-layered structure of different materials were introduced, it has become difficult to process the gates under a single etching condition, and from then on, methods for processing gates via several steps under multiple conditions have been adopted. In such method, gas flow rates and gas pressures are fluctuated for ten seconds or longer immediately after switching conditions. In order to prevent gates from being etched under uncertain fluctuated conditions by which reproducibility is deteriorated, a method has been adopted in which plasma discharge is discontinued between steps (non-continuous discharge).

However, this method had two drawbacks. One is the deterioration of throughput. Since it took ten or more seconds to switch conditions, the processing time is increased when the number of switching of conditions is increased. Another problem is the increase of product defects. Normally, a large amount of particles are generated in the processing chamber during etching. The particles are trapped in a portion called an ion sheath existing at an interface between the plasma and the wafer, and are attached to the wafer the instant the etching is terminated and plasma discharge is discontinued. The attached particles are removed through wet cleaning process, and rarely cause product defects. On the other hand, if the process adopts a non-continuous discharge, the particles are attached to the wafer by discontinuing discharge during the etching process. Thereafter, when etching is resumed, the areas directly below the attached particles are not etched, and non-etched portions are created. Therefore, even when the particles are removed by wet cleaning process, the non-etched portions remain and become the cause of product defects.

In order to reduce such product defects, some semiconductor device manufacturers are examining a method to not discontinue discharge between steps, that is, to perform continuous discharge. Many of the proposed continuous discharge methods provide an intermediate step between steps so as to suppress etching during switching of gases by diluting processing gas with a rare gas or other gases having little reactivity. However, even by adopting this method, it is impossible to avoid deterioration of throughput since the time required for switching gases is not reduced.

In order to improve throughput, it is necessary to perform continuous discharge without adopting intermediate steps. In such case, it is necessary to switch the gas flow rates and gas pressures smoothly with superior reproducibility and at high speed. However, in a gas switching system normally used for etching, the response property in switching gases is not good.

FIG. 25 shows the actual arrangement of a gas line used in the prior art apparatus. The arrangement of FIG. 25 is described taking as an example the sequence for switching from gas supply source 101 to gas supply source 111. In the step regarding the gas supply source 101, the flow rate of MFC 102 attached to a gas line of the gas supply source 101 is set to a desirable value, and a valve 103 disposed on a processing gas line 8 communicating the MFC 102 and a vacuum processing chamber is opened. Simultaneously when the signal for switching gases is entered, the flow rate of MFC 102 is set to 0 sccm, the valve 103 is closed, the valve 113 is opened, and the flow rate of MFC 112 of the gas supply source 111 is set to a desirable value. FIG. 26 shows the response of gas flow rate of gases from gas supply sources 101 and 102 and the response of pressure. Since the valve response is extremely good, the flow rate of gas supply source 101 becomes 0 sccm immediately after switching steps, but since the flow rate response of MFC is not good, the starting of flow from gas supply source 111 is delayed for approximately one second. Therefore, gas is not supplied for a few seconds immediately after switching gases, by which undershoot of pressure occurs immediately after switching gases.

Furthermore, since a very small amount of gas flows even when the MFC is set to 0 sccm, gas from the gas supply source 111 is pooled between the MFC 112 and the valve 113 when the valve 113 is closed for a long period of time. FIG. 27 shows the response of flow rate and pressure at this time. At the instant the valve 113 is opened, a large amount of gas from gas supply source 111 is supplied, and the flow rate of gas supply source 111 overshoots. At this time, the processing chamber pressure also overshoots, and it takes a few seconds for the pressure to become steady. Thus, another drawback occurs in that etching reproducibility is deteriorated. Furthermore, in the actual etching apparatus, since a shower plate structure or a nozzle structure for injecting gas through small holes is adopted as the gas supplying mechanism, the response property becomes even more complex.

One art for switching the gas flow rate at high speed is a high-speed gas flow rate control method utilized mainly in MO-CVDs. FIG. 28 illustrates an actual arrangement of the gas line for the high-speed gas flow rate control method. In FIG. 28, an exhaust gas line 9 communicating an MFC 3 and an exhaust pump 5 is disposed in addition to the processing gas line 8 communicating a gas supply source 4, an MFC 3, a vacuum processing chamber 6 and an exhaust means 7, wherein valves 1 and 2 are respectively attached to the gas lines. During gas supply, the valve 2 is opened while valve 1 is closed, the flow rate Qo of MFC 3 is set to the same value as the flow rate Q for processing, and gas is supplied toward the exhaust pump 5. When flow rate Qo is stabilized, the valve 2 is closed and valve 1 is opened simultaneously, by which a high-speed gas supply is realized. Further, Japanese Patent Application Laid-Open Publication No. 5-198513 (patent document 1) discloses an example of a method for setting the flow rate Qo supplied to the exhaust gas line 9 to a value smaller than the flow rate Q for processing in order to prevent the occurrence of an overshoot at the start of supplying gases caused by the pressure P in the exhaust gas line 9 being higher than a pressure Po in the processing gas line 8.

In order to realize continuous discharge, it becomes necessary to switch the gas flow rate and the gas pressure smoothly with high reproducibility and at high speed in a shower plate structure or a nozzle structure which are gas supplying mechanisms specific for performing etching. Especially in recent gate etching processes, the processing time of each step has become shorter, so that a high-speed switching of gases of 1 s or faster is required. However, the high-speed gas flow rate control system disclosed in patent document 1 does not take into consideration the effect of shower plate structures or nozzle structures. Therefore, prior to discovering the present invention, the present inventors have applied the gas flow rate control system disclosed in patent document 1 to a shower plate mechanism and measured the response during switching of gases.

FIG. 29 shows the actual structure by which response was measured. In FIG. 29, an exhaust gas line 9 communicating an MFC 102 and an MFC 112 to an exhaust pump 5 is provided in addition to a processing gas line 8 communicating an MFC 102 and an MFC 112 to a gas reservoir 10, gas feed holes 11 of a shower plate and a processing chamber, wherein valves 103, 104, 113 and 114 are provided to the gas lines. In the step regarding the gas supply source 101, the valve 104 on the exhaust gas line of the gas supply source 101 is closed, the valve 103 provided to the processing gas line 8 is opened, and a desired flow quantity of gas is supplied via the MFC 102 to the vacuum processing chamber. Furthermore, at this time, regarding the gas supply source 111 used in the subsequent step, the valve 113 is closed, the valve 114 is opened, and a flow rate of gas to be used in the subsequent step is supplied via the MFC 112 to the exhaust gas line 9. When switching from gas supply source 101 to gas supply source 111, the valve 114 and the valve 103 are closed simultaneously as the valve 113 is opened. The pressure fluctuation in the processing chamber at this time is monitored, and it has been discovered that pressure undershoot occurs immediately after the gases are switched. In addition, it has been discovered that the degree of undershoot had no reproducibility, and that large and small undershoots occurred.

In addition, the gas composition in the processing chamber immediately after switching gases was examined using plasma emission spectrometry, and it has been discovered that the increase in ratio of the gas supplied by gas supply source 111 was extremely slow, and it took about 10 s to completely switch from gas supplied by gas supply source 101 to gas supplied by gas supply source 111. In other words, it has been discovered that the prior art arrangement had the drawbacks of (1) undershoot and (2) low response. Continuous discharge was performed in the above arrangement, and it has been discovered that the arrangement had the drawbacks of (1) particles adhering to the wafer by the sudden drop of pressure immediately after switching conditions by which plasma is extinguished, and (2) gases not being switched completely in a short time by which it becomes difficult to achieve a stable etching property.

### SUMMARY OF THE INVENTION

The object of the present invention is to provide a plasma etching apparatus and a plasma etching method capable of switching gas flow rates and gas pressures smoothly with superior reproducibility and at high speed in a shower plate structure or a nozzle structure.

The present inventors have examined pressure undershoot, and discovered that undershoot is caused by back flow of gas, and that there are two mechanisms related to the back flow of gas. The first mechanism is described with reference to FIG. 29. In a shower plate structure or a nozzle structure, the inner diameter of the holes 11 for introducing gas into the vacuum processing chamber 6 is smaller than the inner diameter of the processing gas line 8, by which the gas flow is somewhat hindered. Thus, the pressure Po in the processing gas line 8 becomes significantly higher than the pressure P1 in the exhaust gas line 9. At the instant the valve 113 is opened and the valve 114 is closed, the pressure in the area of the gas pipe 115 surrounded by the valve 113, the valve 114 and the MFC 112 is P1, which is smaller than the pressure Po of the processing gas line 8, so that back-flow of gas occurs from the processing gas line 8 to the gas pipe 115. This back-flow phenomenon caused by the first mechanism occurs with high reproducibility.

The second mechanism occurs as follows. When valves 113 and 114 are opened and closed simultaneously as described in patent document 1, there occurs an instant when the valve 113 is not completely opened and the valve 114 is slightly opened. The processing gas line 8 and the exhaust gas line 9 are communicated during this time, so that back flow of gas occurs from the processing gas line 8 having a higher pressure to the exhaust gas line 9. The back flow caused by the second mechanism is influenced by the dispersion of the degree of opening or closing of the valves 113 and 114 during switching of gases, so that the degree of back flow is dispersed.

A first method for preventing undershoot is illustrated in FIG. 1, wherein a variable conductance valve 100 is disposed in the exhaust gas line 9 so as to control the pressure P1 of the exhaust gas line 9 to be equal to or greater than the pressure Po of the processing gas line 8 and equal to or smaller than 1.2 times the pressure Po. Thus, the back flow of gas from the processing gas line 8 to the exhaust gas line 9 is prevented completely.

A second method for preventing undershoot is to set a volume V1 of the portion of the gas pipe 115 to be sufficiently smaller than a total volume Vo of the volume of the processing gas line 8 from the valve 113 to the gas reservoir 10 and the volume of the gas reservoir 10. According to this arrangement, undershoot caused by mechanism 1 can be reduced even if there is some difference in pressure between P1 and Po.

A third method for preventing undershoot is to open the valve 113 after closing the valve 114, instead of opening and closing the valves 113 and 114 simultaneously. This arrangement enables to prevent the back flow of gas caused by mechanism 2.

In addition, the exhaust pump 5 can also be used as a pump for discharging the back pressure of the exhaust means 7.

Next, the present inventors have examined the cause of low response, and discovered two most significant factors. One factor is that smooth gas flow is prevented since the inner diameter or number of the gas feed holes 11 of the shower plate is small. This is considered to have prevented the gas composition from being changed smoothly after the valves are switched, since gas flow was stagnated in the space of volume Vo. The present inventors have succeeded in discovering that when the inner diameter of the gas feed holes 11 is smaller than the inner diameter of the pipe of the processing gas line, the gas response depends on expression 1.

$$U = \frac{{d}^{2}}{{V}_{o}} \sqrt{\frac{Q \cdot N}{t}} \qquad [ Expression 1 ]$$

In the expression, t represents the depth of the gas feed holes 11, d represents the diameter of the holes, N represents the number thereof, and Q represents gas flow rate (Pa·m³/s). High-speed response can be realized by increasing this value.

By applying the present invention to multi-step plasma etching, it becomes possible to perform processing via continuous discharge without having to provide intermediate steps, by which the throughput is improved. Furthermore, since the pressure fluctuation during switching of steps is small and the discharge does not become unstable, it becomes possible to reduce the product defects caused by particles significantly.

### BRIEF DESCRIPTION OF THE DRAWINGS

FIG. 1 is an explanatory view of the etching apparatus according to the present invention;

FIG. 2 is an explanatory view showing the etching apparatus according to embodiment 1;

FIG. 3 is an explanatory view of the arrangement of a gas supply unit according to embodiment 1;

FIG. 4 is an explanatory view showing the time variation of the flow rate of gas supply source 111 immediately after switching gases;

FIG. 5 is an explanatory view of the relationship between U and gas response;

FIG. 6 is an explanatory view of the time variation of the processing chamber pressure immediately after switching gases according to the prior art;

FIG. 7 is an explanatory view of the relationship between processing chamber pressure fluctuation ΔP and inner pressure P1 of gas pipe 115;

FIG. 8 is an explanatory view of the valve switch sequence before improvement;

FIG. 9 is an explanatory view of the valve switch sequence after improvement;

FIG. 10 is a chart showing the etching conditions before improvement;

FIG. 11 is an explanatory view of the time variation of processing chamber pressure during processing before improving conditions;

FIG. 12 is a chart showing the etching conditions after improvement;

FIG. 13 is an explanatory view of the etching apparatus according to embodiment 3;

FIG. 14 is an explanatory view of the gas feed mechanism or shower plate structure of embodiment 3;

FIG. 15 is a chart showing the etching conditions according to embodiment 3;

FIG. 16 is an explanatory view of the cross-sectional structure of the sample being etched according to embodiment 3 with non-continuous discharge;

FIG. 17 is an explanatory view of the processed cross-sectional structure of the sample being etched before improvement;

FIG. 18 is an explanatory view of the time variation of supplied microwave power and vacuum processing chamber pressure by adopting non-continuous discharge;

FIG. 19 is an explanatory view of the time variation of supplied microwave power and vacuum processing chamber pressure by adopting continuous discharge before improvement;

FIG. 20 is an explanatory view of the relationship between vacuum processing chamber pressure and etching rate of silicon and silicon oxide film according to the conditions of step 3;

FIG. 21 is a chart describing the etching conditions after improvement;

FIG. 22 is an explanatory view showing the time variation of vacuum processing chamber pressure by adopting continuous discharge after improvement;

FIG. 23 is an explanatory view of the etching apparatus of embodiment 4;

FIG. 24 is an explanatory view of the etching apparatus of embodiments 5, 6 and 7;

FIG. 25 is an explanatory view of the arrangement of a normal gas supply unit according to the prior art;

FIG. 26 is an example of an explanatory view of the time variation of gas flow rate and pressure immediately after switching gases in a normal gas supply unit according to the prior art;

FIG. 27 is an example of an explanatory view of the time variation of gas flow rate and pressure immediately after switching gases in a normal gas supply unit according to the prior art;

FIG. 28 is an explanatory view of the arrangement of the gas supply unit according to patent document 1; and

FIG. 29 is an explanatory view of the example of an etching apparatus to which the gas supply unit of patent document 1 is applied.

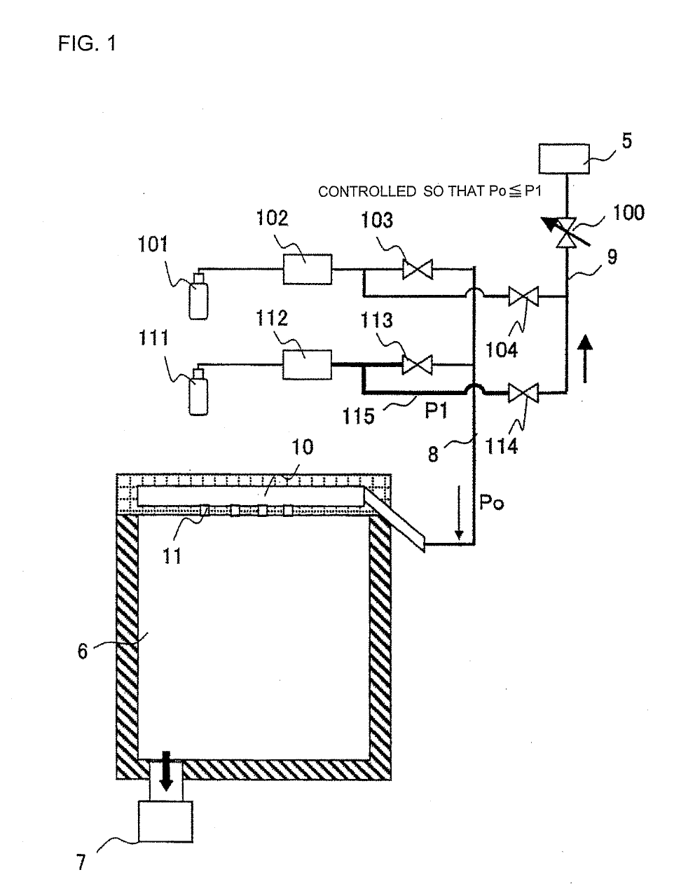

### DETAILED DESCRIPTION OF THE PREFERRED EMBODIMENTS

### Embodiment 1

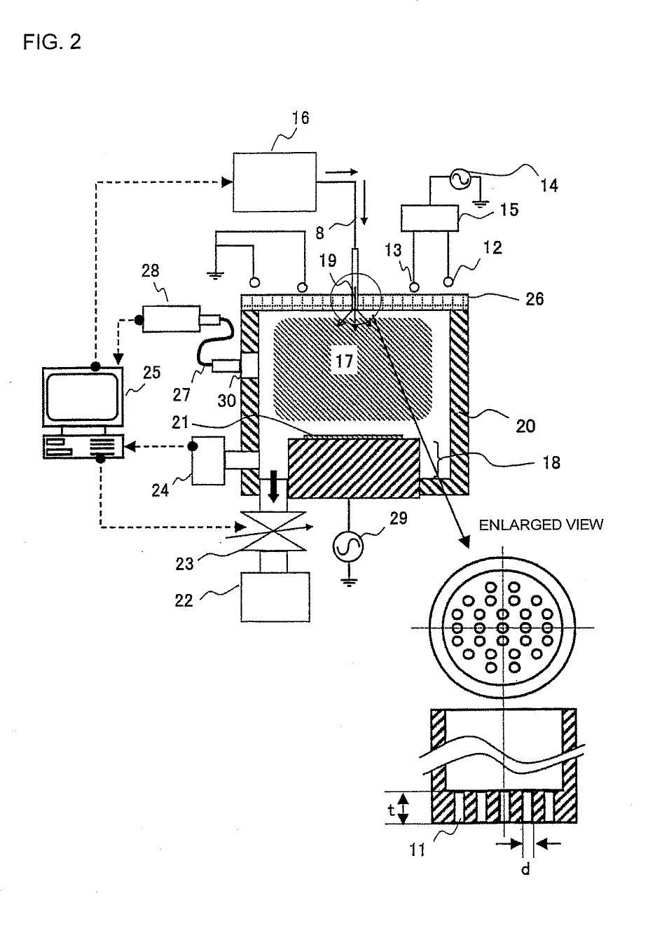

The configuration of an apparatus according to one preferred embodiment of the present invention is illustrated in FIG. 2. In the apparatus of FIG. 2, etching gas is supplied from a gas supply unit 16 via a processing gas line 8 and a gas feed mechanism 19 into a vacuum processing chamber 20, and an RF power of 13.56 MHz for example is applied from a discharging RF power supply 14 via an antenna coil 13 and an antenna coil 12 disposed outside a dielectric window 26 made of alumina, so as to generate inductively-coupled plasma 17 from the etching gas. A power distributor 15 is disposed between the antenna coils 12, 13 and the discharging RF power supply 14 for controlling the ratio of power supply to the antenna coils 12 and 13, by which the distribution of plasma generation can be controlled. Etching is performed by irradiating the plasma 17 on a sample 21 placed on a sample stage 18. A bias RF power supply 29 is connected to the sample stage 18, and the sample 21 can be etched efficiently by applying an RF power of 13.56 MHz, for example. Furthermore, the pressure in the vacuum processing chamber 20 can be controlled via a turbo-molecular pump 22 and a variable conductance valve 23. The pressure is measured by a capacitance manometer 24 disposed above the variable conductance valve 23, and the pressure can be maintained at a predetermined value by performing feedback-control of the opening of the variable conductance valve 23 based on the measured value.

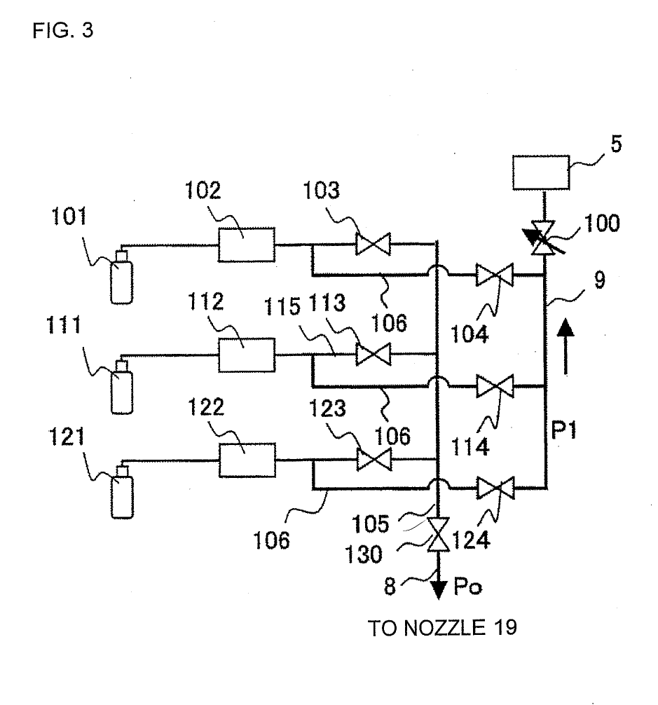

A quartz observation window 30 is formed on the side wall of the processing chamber, to which is connected a spectroscopy system 28 via an optical fiber 27 in order to analyze the plasma emission and determine the timing for switching conditions. Based on the order to switch conditions from the spectroscopy system 28, a computer 25 instructs the subsequent conditions to various units of the apparatus including the gas supply unit 16. The arrangement of the gas supply unit 16 is illustrated in FIG. 3. In FIG. 3, each gas line is equipped with an MFC 102, 112 or 122 and a valve 103, 113 or 123, respectively, and all of the gas lines are connected to a gas pipe 105 at the downstream side of the valve 103, 113 or 123, which is communicated via a valve 130 and a processing gas line 8 to the nozzle 19.

In addition, exhaust gas lines 106 connected to an exhaust pump 5 are disposed between the MFCs 102, 112 and 122 and the valves 103, 113 and 123, and the gas lines are each equipped with a valve 104, 114 or 124. Furthermore, a variable conductance valve 100 (piezo-valve) is attached to the exhaust gas line 9, which controls the pressure P1 of the exhaust gas line 9. An example is described in which the gas supply source 101 is switched to gas supply source 111 in the above-mentioned gas supply unit. In the step regarding gas supply source 101, the valve 104 of the exhaust gas line of the gas supply source 101 is closed, and the valve 103 attached to the processing gas line 8 is opened, so that a predetermined flow of gas is supplied via the MFC 102 to the vacuum processing chamber 6. At this time, regarding the gas supply source 111 to be used in the subsequent step, the valve 113 is closed and the valve 114 is opened, so that the gas flow rate to be used in the subsequent step is supplied via the MFC 112 to the exhaust gas line 9. When switching from gas supply source 101 to gas supply source 111, the valve 113 is opened, and simultaneously, the valves 114 and 103 are closed.

Next, the change of flow rate of gas supply source 101 is described as an example on how the flow rate is changed. In the former step, the valve 103 and the variable conductance valve 100 are opened, and the flow rate of the MFC 102 is set to Q1. Simultaneously when the switching of conditions is instructed, the value of the MFC 102 is set to Q2.

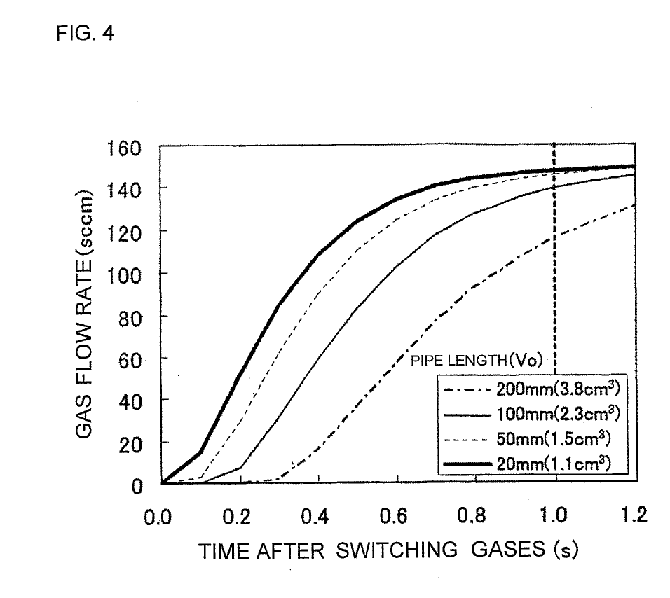

The response of gas flow rate was examined with the opening of the variable conductance valve 100 adjusted so that Po=P1, using a gas feed mechanism 19 having 27 nozzle-like gas feed holes 11 each having a diameter d of 0.1 mm and a depth t of 7 mm, as illustrated in the enlarged view of FIG. 2. FIG. 4 shows the result of the change in response of the flow rate of the gas supply source 111 when the gas supply source 101 is switched to the gas supply source 111, with the size of the Vo changed by varying the pipe length of the processing gas line 8. A standard quarter-inch stainless steel pipe is used as the gas pipe of the processing gas line 8. As shown in FIG. 4, the response improves as the pipe length of the processing gas line 8 is shortened and the Vo is reduced, and it is recognized that by reducing the pipe length to 20 mm and the Vo to 1.1 cm³, it becomes possible to set the flow rate to the predetermined value of 150 sccm within the target time of 1 s.

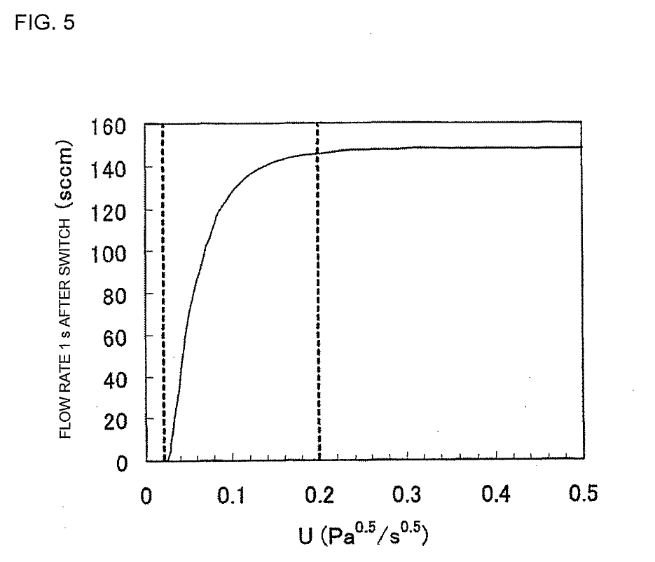

FIG. 5 shows the above results, taking value U of expression 1 on the horizontal axis, and illustrating the correlation with the gas flow rate at 1 s after switching gases. Here, t represents the hole depth of the gas feed holes 11, d represents the hole diameter, n represents the number of holes, and Q represents the gas flow rate (Pa·m³/s). When the value of U is sufficiently high, the gas flow rate after 1 s becomes the set flow rate of 150 sccm. On the other hand, when the value of U becomes equal to or smaller than 0.2 (Pa^{0.5}/s^{0.5}), the flow rate is reduced rapidly, and when it becomes equal to or smaller than 0.02 (Pa^{0.5}/s^{0.5}), the flow rate completely falls to 0 sccm. Therefore, in order to switch gases at 1 s or smaller, it is necessary to set the value of U to at least 0.02 (Pa^{0.5}/s^{0.5}), preferably greater than 0.2 (Pa^{0.5}/s^{0.5}).

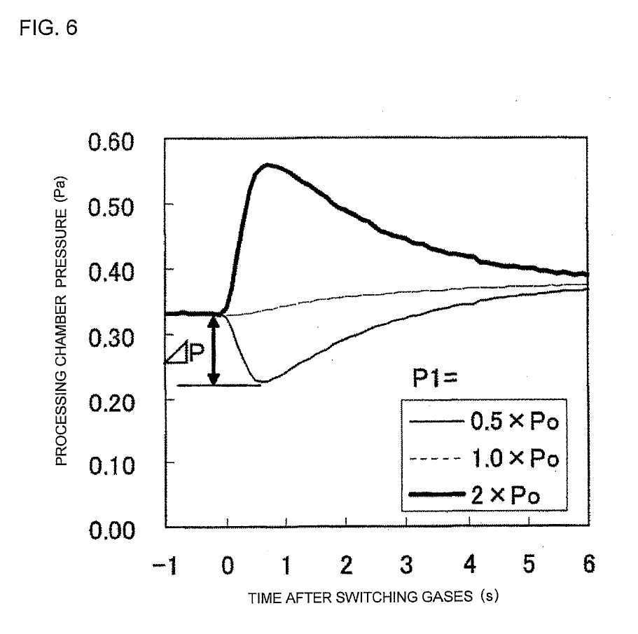

Next, using the nozzle structure described above, the pressure fluctuation during switching of gases was examined with the pipe length of the processing gas line 8 set to 20 mm and the opening of the variable conductance valve 100 varied. FIG. 6 shows the result of examining the pressure fluctuation during switching of gases, with the value of Po set to 22 kPa and the value of P1 set to 0.5 times, 1 times and 2 times the value of Po. Undershoot occurs when P1 is small and overshoot occurs when P1 is high. The cause of this phenomenon was examined. When P1 is small, gas back-flows to the portion of the gas pipe 115 surrounded by the valve 113, the valve 114 and the MFC 112, and on the other hand, when P1 is high, the gas in the gas pipe 115 blows out instantly.

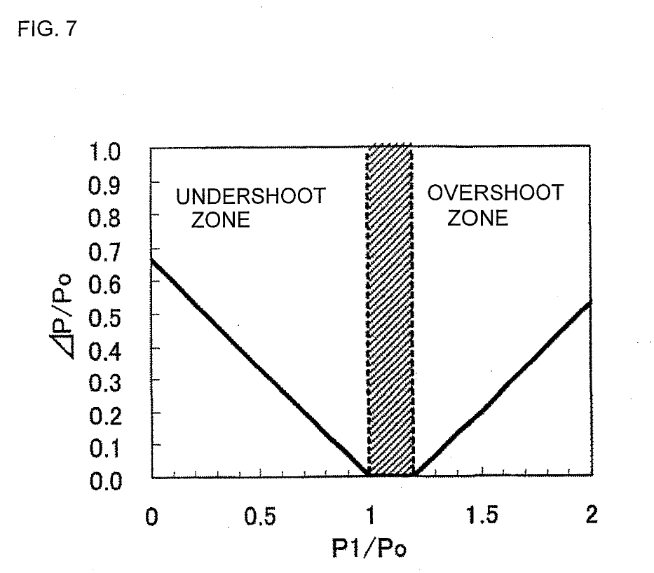

Next, FIG. 7 shows the examined result of the relationship between the pressure fluctuation quantity ΔP during switching of gases and P1. It can be seen that a zone where no overshoot or undershoot occurs exists in the range of 1 to 1.2 times the value of Po. Therefore, by setting the value of P1 to fall within this range, it becomes possible to realize smooth switching of gases without causing any undershoot or overshoot.

In order to control the undershoot by the opening of the variable valve, it becomes necessary to constantly control the opening of the variable valve corresponding to the gas flow rate or the gas types, by which the cost of the apparatus is increased. Therefore, a method was examined to prevent undershoot without using the variable valve.

With the variable conductance valve 100 fully opened, the pressure of Po is 22 KPa whereas the pressure of P1 is as low as 50 Pa, so that a large undershoot occurs by the back flow. The relationship between the pressure fluctuation quantity ΔP at this time and the volume V1 of the gas pipe 115 was computed via computer simulation, and as a result, the relationship was found to be expressed by the following expression: ΔP=Po×V1/(V1+Vo).

Thus, for example, in order to suppress the pressure fluctuation ΔP to 10% or smaller, it is required that V1 is set to 11% or smaller of the value of Vo. According to the present experimental system, in order to suppress V1 to 11% or smaller of the value of Vo, the pipe length of the gas pipe 115 must be set to 3 mm or smaller. However, if the valves 113 and 114 and the MFC 112 are connected by normal gas pipes, it is extremely difficult to reduce the pipe length to 3 mm or smaller. Therefore, in order to minimize the length of the gas pipe 115, an integrated gas system to which the valves and MFC are directly connected was adopted. A condition of Vo>>V1 was realized according to this method, and by examining the pressure response during switching of gases, it was confirmed that no undershoot of pressure occurred and a smooth switching of gases was realized.

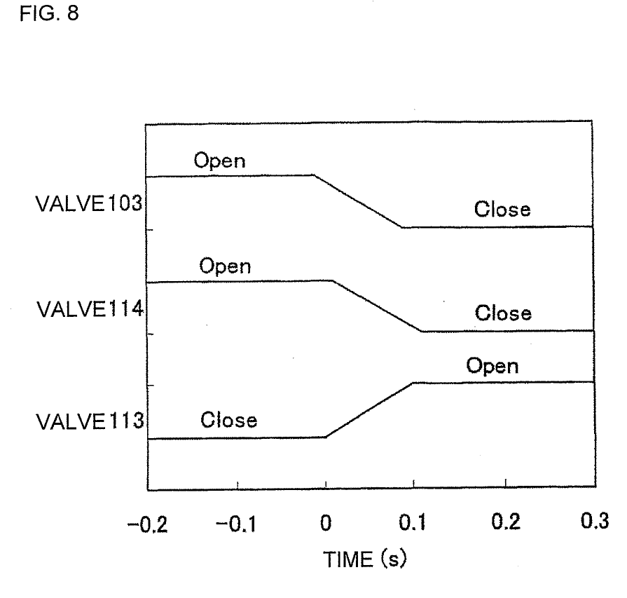

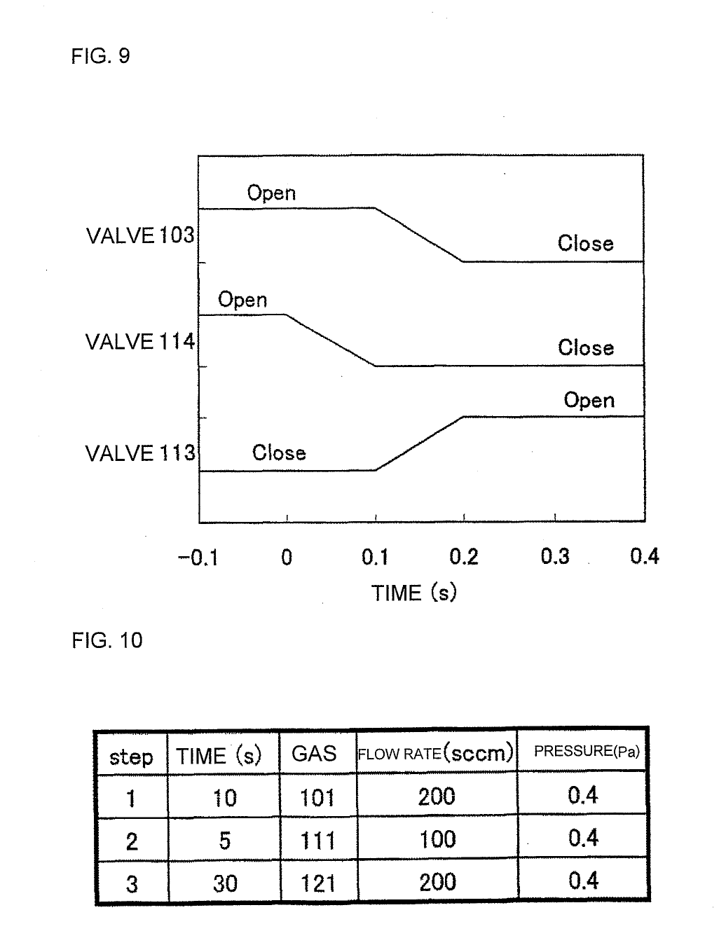

Using the above-mentioned arrangement, gas switching tests were repeated in order to perform a reproducibility test, and the occurrence of undershoots were examined. As a result, it was discovered that undershoot occurs randomly at a rate of 5%. A sequence chart in FIG. 8 showing the switching from gas supply source 101 to gas supply source 111 is referred to in describing the cause of such phenomenon. During 0 s to 0.1 s at the time of switching gases, the valves 103 and 114 are not completely closed, and the valve 113 is starting to open. At this instant, the processing gas line 105 and the exhaust gas line 106 are communicated via valves 113 and 114, so that back flow of gas occurs from the processing gas line 105 having higher pressure to the exhaust gas line 106. By this back flow, undershoot of pressure occurs during switching of gases. The level of undershoot is greatly dispersed since it depends on how the valves are closed during time 0 s to time 0.1 s. Therefore, as shown in FIG. 9, the valve switching sequence was changed so that the valve 113 opens after the valve 114 is closed. As a result of the reproducibility test performed by this sequence, not a single undershoot occurred during the test repeatedly performed for 1000 times.

The gas supply source was switched from gas supply source 101 to gas supply source 111 while performing continuous discharge in a hardware in which undershoot occurs and in a hardware in which no undershoot occurs. As a result, a stable plasma discharge was achieved in the hardware in which no undershoot occurs, but discharge flickers during occurrence of undershoot in the hardware in which undershoot occurs. Product processing was performed using these two hardware and the yields thereof were evaluated, and as a result, high yield was achieved in the hardware in which no undershoot occurs, but the yield was significantly deteriorated in the hardware in which undershoot occurs, due to a large number of short circuits caused by unetched portions created by particles.

As described, by using a gas switching system according to the present invention, gases can be switched smoothly at high speed, so that a stable continuous discharge is enabled. It has been discovered that product defects caused by particles can be reduced by the system.

In the present invention, the discharge stability and product yields were evaluated by combining (1) reducing V1 by an integrated gas system and (2) utilizing a valve switching sequence as illustrated in FIG. 9, but a certain amount of effect can be achieved by utilizing method (1) or method (2) alone. Furthermore, similar effects as achieved by combining methods (1) and (2) can also be achieved by utilizing method (3) in which P1 is controlled by a variable conductance valve 100. Furthermore, an even higher effect can be achieved by combining methods (1), (2) and (3).

Furthermore, according to the present invention, each of the gas lines of MFC 102, MFC 112 and MFC 122 are respectively provided with exhaust gas lines and valves 104, 114 and 124, but similar effects can be achieved by converging the gas lines of MFC 112 and MFC 122, and to provide a single exhaust gas line and a single valve to the converged gas line.

### Embodiment 2

A three step etching as illustrated in FIG. 10 is performed using the configuration of embodiment 1. At this time, a phenomenon occurs in which plasma is extinguished due to the occurrence of pressure undershoot immediately after step 1 and pressure overshoot immediately after step 2, as illustrated in FIG. 11. Thus, the prevent inventors have examined the cause of occurrence of such undershoot and overshot, and considered a method for reducing the same.

According to the present system, since the response of gas flow rate is high and the gas flow rate is changed rapidly, a pressure control mechanism having a slow response cannot follow such change. This is considered to have caused the undershoot and overshoot illustrated in FIG. 11. In order to solve this problem, the present inventors have examined methods to change the gas flow rate in steps.

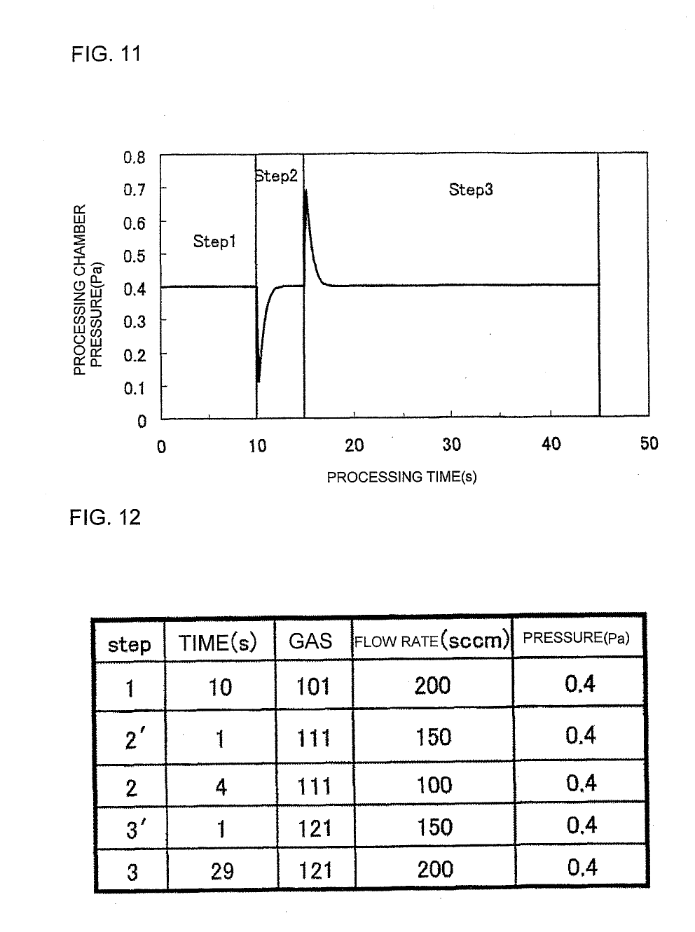

As illustrated in FIG. 12, the flow rate of MFC 112 is set to 150 sccm for the first 1.0 s of step 2, and thereafter, the flow rate is reduced to 100 sccm. Similarly, the flow rate of MFC 122 is set to 150 sccm for the first 1.0 s of step 3, and thereafter, the flow rate is increased to 200 sccm. The change in pressure at this time was examined, and it was discovered that the undershoot and overshoot of pressure was reduced by reducing or increasing the gas flow rate in steps. Thus, it becomes possible to maintain a stable discharge even during switching of steps.

As described, regarding the undershoot and overshoot of pressure occurring due to the change in flow rate between steps 1 and 2, it has been discovered that by utilizing the gas flow rate switching method of the present invention, the undershoot of pressure can be reduced by setting the flow rate to an intermediate flow rate between step 1 and step 2 when starting step 2. By utilizing this method, it becomes possible to significantly reduce product defects caused by particles, since no plasma extinction occurs during switching of steps even when continuous discharge is performed.

### Embodiment 3

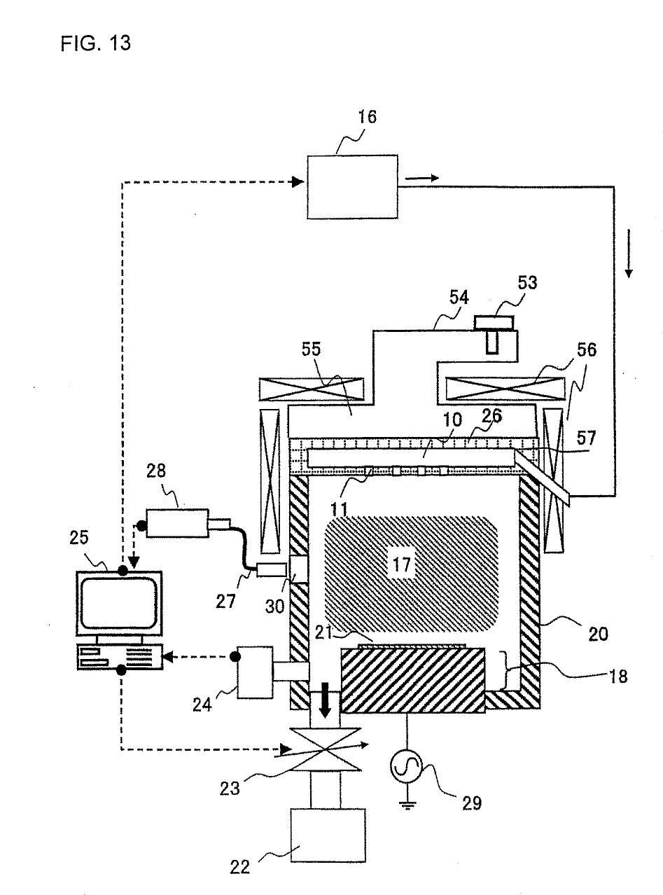

FIG. 13 illustrates an arrangement in which the gas switching system of embodiment 1 is applied to a microwave etching apparatus. In the apparatus of FIG. 13, the etching gas is supplied from a gas supply unit 16 via a gas reservoir 10 disposed in the interior of a dielectric window 26 formed of quartz and through multiple holes (a shower plate structure) disposed on the side facing the vacuum processing chamber of the dielectric window 26 and into the vacuum processing chamber. Further, microwaves generated via a magnetron 53 is supplied via a waveguide 54, a cavity resonator 55 and a dielectric window 26 into the vacuum processing chamber, wherein a plasma 17 is generated by the interaction between the microwaves and the magnetic field created via coils 56. In the apparatus, the volume of the vacuum processing chamber is 150 L, which is relatively large so as to improve the stability of pressure control. The other arrangements are the same as that of embodiment 1. As an example of the shower plate structure, a plate having five gas feed holes 11 each having a hole diameter of 1 mm and a depth of 10 mm is used. As an example of the gas reservoir 10, a cylindrical cavity structure having a diameter of 500 mm and a thickness of 2 mm is used.

Using this apparatus, the flow rate response of gas supply source 111 was examined by switching from gas supply source 101 to gas supply source 111. As a result, it was discovered that the response is extremely poor, taking approximately 5 s to achieve the set flow rate of 150 sccm. The cause of such poor response rate was examined, and it was discovered that the value of U was small due to the large volume of the gas reservoir 10. The diameter of the gas reservoir 10 cannot be reduced since a gas feed port 57 is formed at the outermost circumference thereof. Therefore, the thickness of the gas reservoir 10 was reduced to 0.1 mm in order to reduce the volume of the gas reservoir 10. A similar test was conducted by this arrangement, and it has been discovered that the gas flow rate response was even more deteriorated. This is caused by the gas flow path from the gas feed port 57 to the gas feed holes 11 being narrowed down significantly, by which smooth flow of gas is prevented.

Based on the above examination, it has been discovered that it is impossible to reduce Vo using a shower plate since the capacity of the gas reservoir is large.

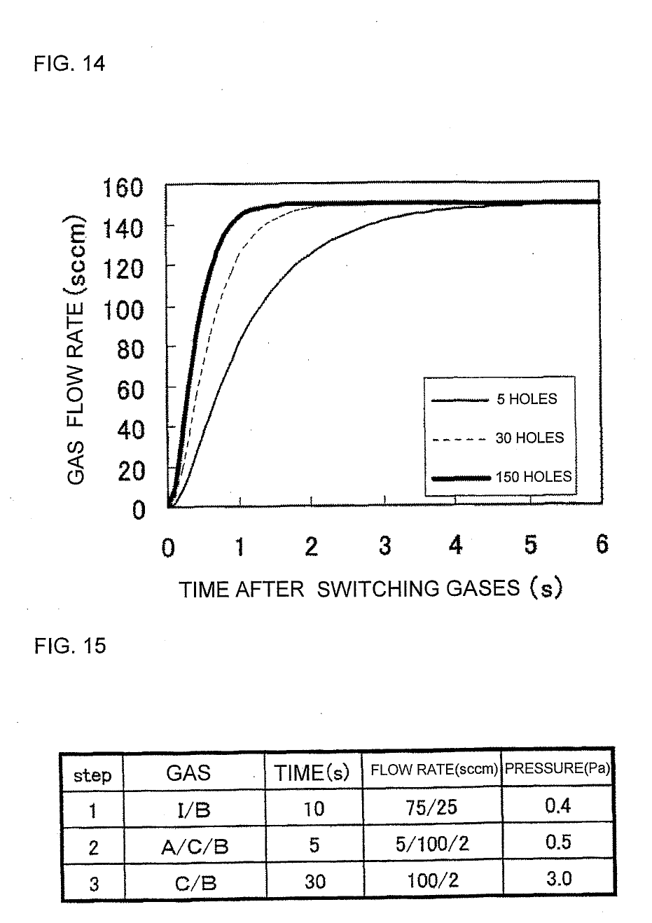

Therefore, the present inventors have examined a method to improve the response by increasing the value of U by increasing the number of gas feed holes 11 on the shower plate. The response of gas flow rates when the number of gas feed holes 11 are increased to 30 and to 150 are shown in FIG. 14. The response property is improved as the number of holes increases, and when 150 holes are provided, the flow rate reaches the set flow rate of 150 sccm at 1 s.

According to the present embodiment, the response property is improved by increasing the value of U by increasing the number of holes, but a similar effect can be achieved by enlarging the diameter of the holes.

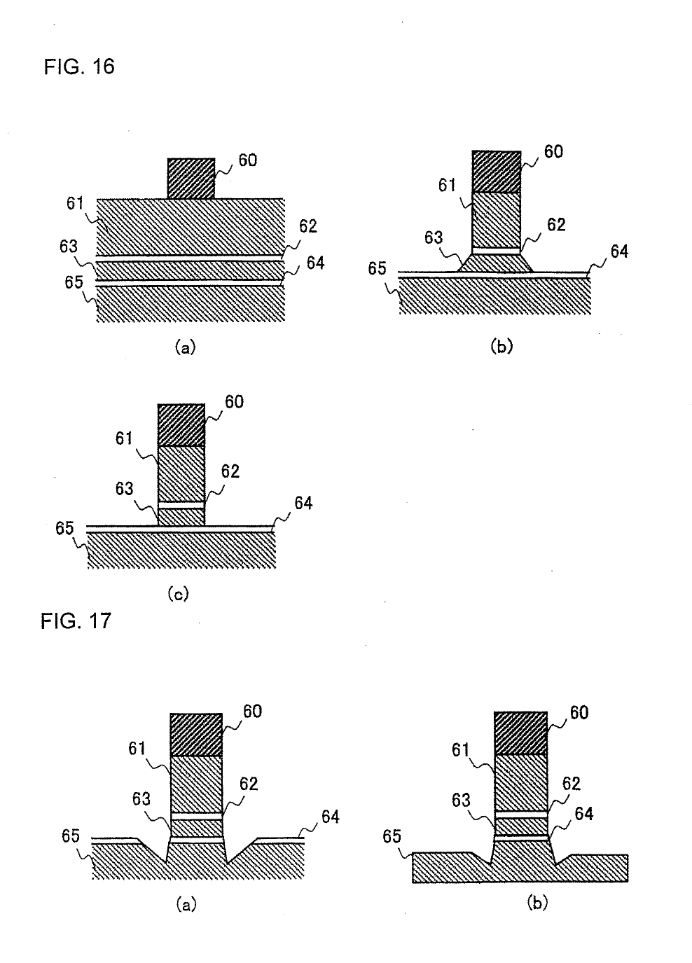

A shower plate provided with 5 holes or 150 holes was attached to the apparatus, and a sample having the structure illustrated in FIG. 16A was processed via the three step etching of FIG. 15. In the present etching process, a polysilicon 61, a silicon oxide film 62 and a polysilicon 63 must be etched along a resist pattern mask 60 so as to leave an unetched silicon oxide film 64 and substrate silicon 65. In the first step, the polysilicon 61 and the silicon oxide film 62 are etched. In the second step, the polysilicon 63 is etched until the silicon oxide film 64 is exposed. The process profile at this time is shown in FIG. 16B, wherein the polysilicon 63 is tapered. In the third step, the skirt portion of the taper is etched and removed. At this time, a high-pressure condition is utilized in which the etch rate of the silicon oxide film is low, so as not to etch the silicon oxide film 64. By adopting such three step process, a perpendicular process shape as shown in FIG. 16C is expected to be achieved.

Next, samples having the structure shown in FIG. 16A were processed via two methods, non-continuous discharge and continuous discharge, and the process profiles thereof were compared. According to the non-continuous discharge process, a sufficient thickness of silicon oxide film 64 remained unetched regardless of the number of holes on the shower plate, and a process profile equivalent to that of FIG. 16C was achieved. On the other hand, according to the continuous discharge process performed using the shower plate having 150 holes, the silicon oxide film 64 corresponding to the skirt portion of the pattern was gone and a portion of the substrate silicon 65 was etched as shown in FIG. 17A. Further, when a shower plate with 5 holes was used, the silicon oxide film 64 was completely gone as shown in FIG. 17B.

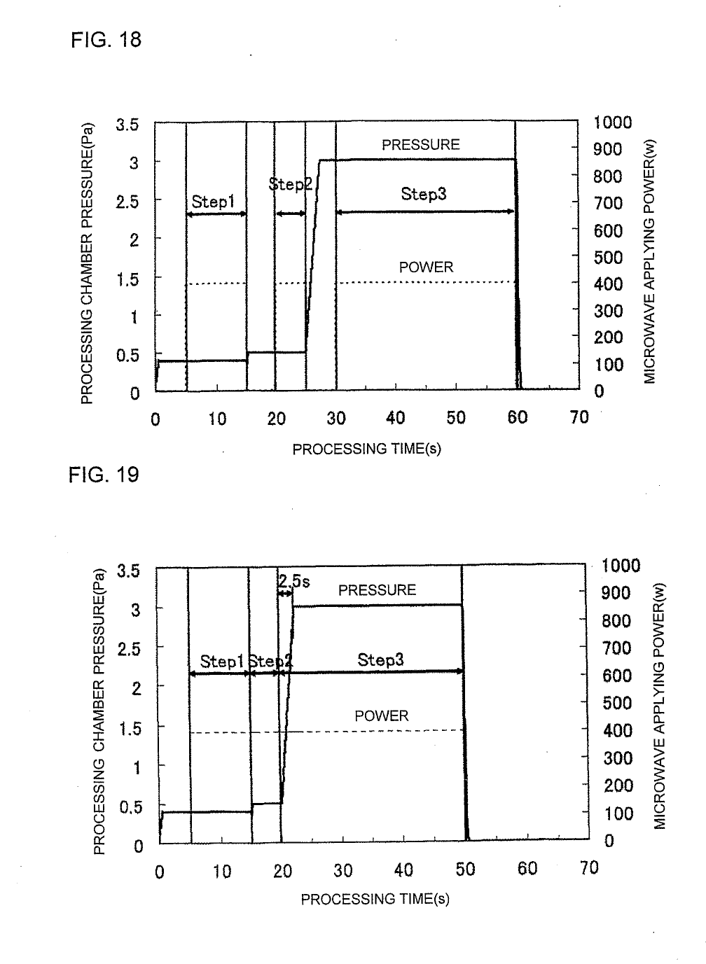

The reason for such difference was examined. FIG. 18 shows the change in pressure and the change in supplied microwave power during the non-continuous discharge process. According to the non-continuous discharge process, a time zone during which no microwave power is applied was provided for the first 5 s of each step so as to perform etching only during a time zone in which pressure is stabilized. FIG. 19 shows the change in pressure and the change in supplied microwave power and reflected power during the continuous discharge process. In the present case, the microwave power was applied until the etching was completed excluding only the first 5 s. Therefore, the etching process was performed even during change of pressure. Especially when step 3 is started, a time zone during which the pressure is gradually increased from 0.5 Pa to 3 Pa exists for approximately 2.5 s, so it is necessary to consider the etching performed during this time.

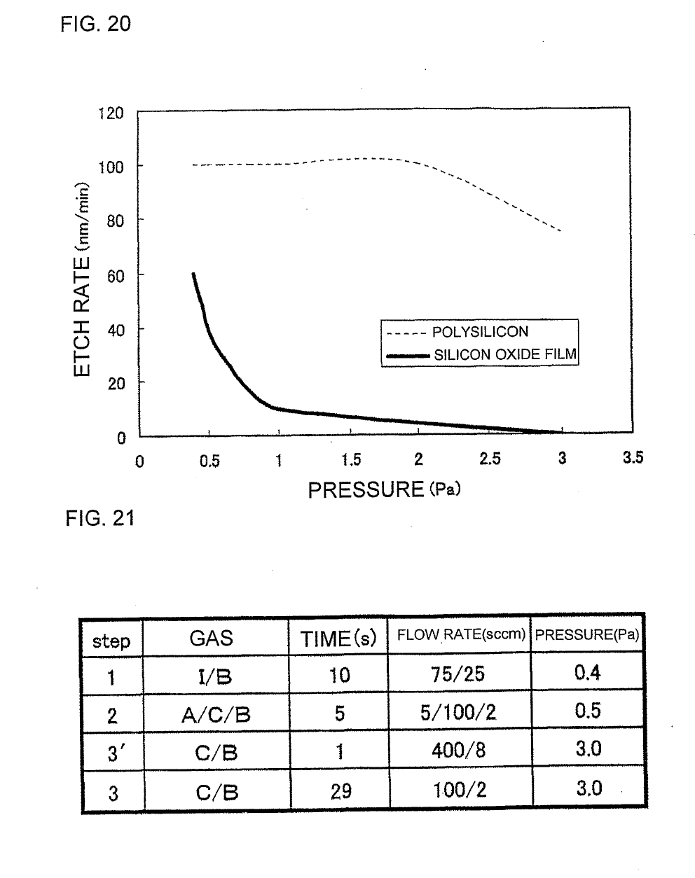

FIG. 20 shows the etch rate of polysilicon and silicon oxide film when pressure is changed from 0.4 Pa to 3 Pa in the gas conditions of step 3. When the pressure is 3 Pa, the etch rate of silicon oxide film is substantially 0 nm/min, whereas when the pressure is lowered, the etch rate of silicon oxide film is increased, and reaches as high as 40 nm/min around 0.5 Pa, which means that the selectivity with silicon is greatly deteriorated. Therefore, when the film thickness of silicon oxide film 64 is small, a portion of the silicon oxide film 64 is considered to have been etched and removed during the 2.5 s after starting step 3 before the pressure reaches 3 Pa.

In addition to this mechanism, when the number of holes on the shower plate is 5, the gas I used in the first step resides during the 5 s of step 2, and the residual gas I is found to have increased the etch rate of silicon oxide film 64.

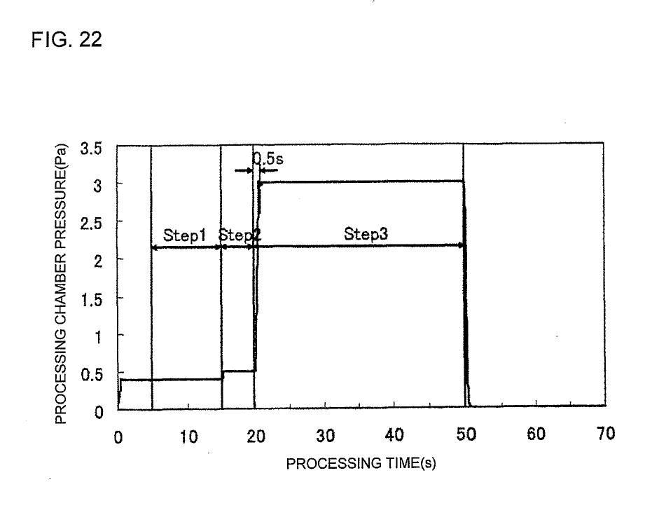

In order to prevent the selectivity from being deteriorated by the former mechanism, the present inventors have considered a method to reduce the rise time of pressure. The rise time of pressure is substantially proportional to the volume of the processing chamber, and inversely proportional to the gas flow rate. Therefore, the present inventors have examined a method to increase the gas flow rates of gas C and gas B during one second at the start of step 3 by four times, or to 400 sccm and 8 sccm, and then to return the flow rates to normal, as shown in FIG. 21. The present inventors have examined the time variation of the total gas flow rate by applying the above-mentioned method to an apparatus having a shower plate with 5 holes and to that having a shower plate with 150 holes. In the test using a shower plate with 5 holes, the actual flow rate was substantially unchanged in such a short time as 1 s since the response property of gas flow rate is low. On the other hand, in the test using the shower plate having 150 holes, the apparatus responded to an instantaneous flow rate change of 1 s since the response property of gas flow rate is high.

The pressure change at this time was examined. It was discovered that the gas flow rate did not change by using a shower plate with 5 holes, so that the same pressure response as that shown in FIG. 19 was realized. On the other hand, when a shower plate with 150 holes was used, the time required for the pressure to reach 3 Pa was reduced to 0.5 s as shown in FIG. 22. The present method was used to etch the sample shown in FIG. 16A, whereas when a shower plate having 5 holes was used, a process profile similar to FIG. 17B was achieved, but on the other hand, when a shower plate having 150 holes was used, a process profile substantially equal to the result in the case of non-continuous discharge was achieved due to the improved selectivity of the silicon oxide film.

As described, if pressure is required to be increased during transition from step 1 to step 2, it becomes possible to achieve the target pressure at a shorter time by utilizing a shower plate structure having superior gas flow rate response, and by setting the gas flow rate to a greater value than the desirable value at the start of step 2 while maintaining a constant gas flow ratio. By utilizing this method, it becomes possible to achieve a processing property equivalent to performing non-continuous discharge even when performing continuous discharge.

A process in which pressure is increased between steps has been taken as an example in the present embodiment, but regarding a process in which pressure is reduced, high-speed pressure control is realized by reducing the flow rate at the start of each step.

### Embodiment 4

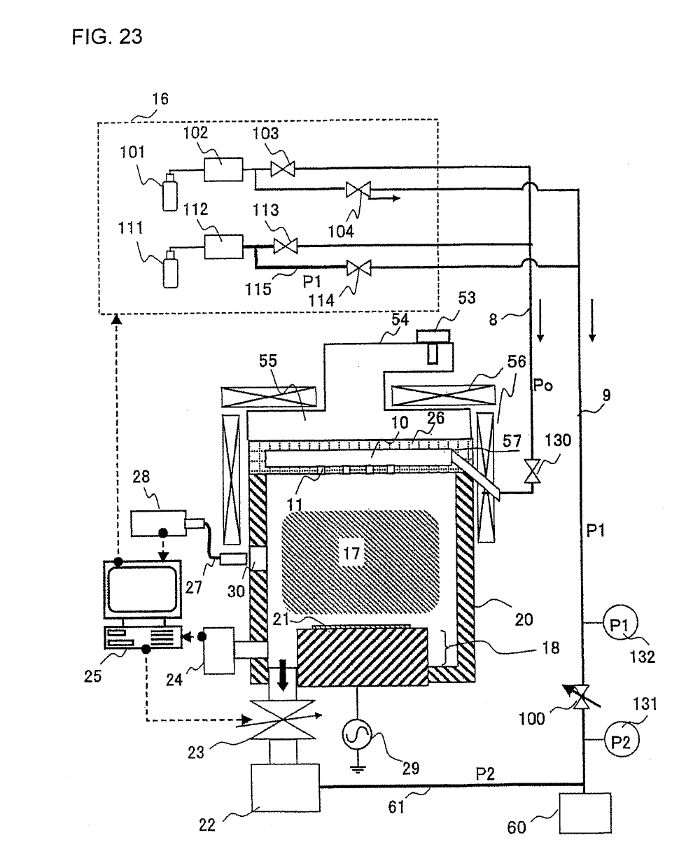

The present inventors have considered using an exhaust pump 5 of an exhaust gas line 9 also as a back-pressure exhaust pump of a turbo-molecular pump (exhaust means) 22 in the apparatus configuration of embodiment 3. One embodiment is shown in FIG. 23. The exhaust gas line 9 is connected via a variable conductance valve 100 to a polysilicon 61 communicating the turbo-molecular pump (exhaust means) 22 and a mask 60. However, by adopting such arrangement, there is a concern that the exhaust gas from the turbo-molecular pump may back flow through the polysilicon 61 via the exhaust gas line 9 into the processing gas line 8. Such back flow may be prevented by controlling the opening of the variable conductance valve 100 and setting a pressure P1 of the exhaust gas line 9 measured via a pressure manometer 132 to be higher than a pressure P2 of the polysilicon 61 measured via a manometer 131. According to the present arrangement, the costs of the apparatus can be cut down since high-speed switching of gases can be realized without increasing the number of exhaust pumps.

### Embodiment 5

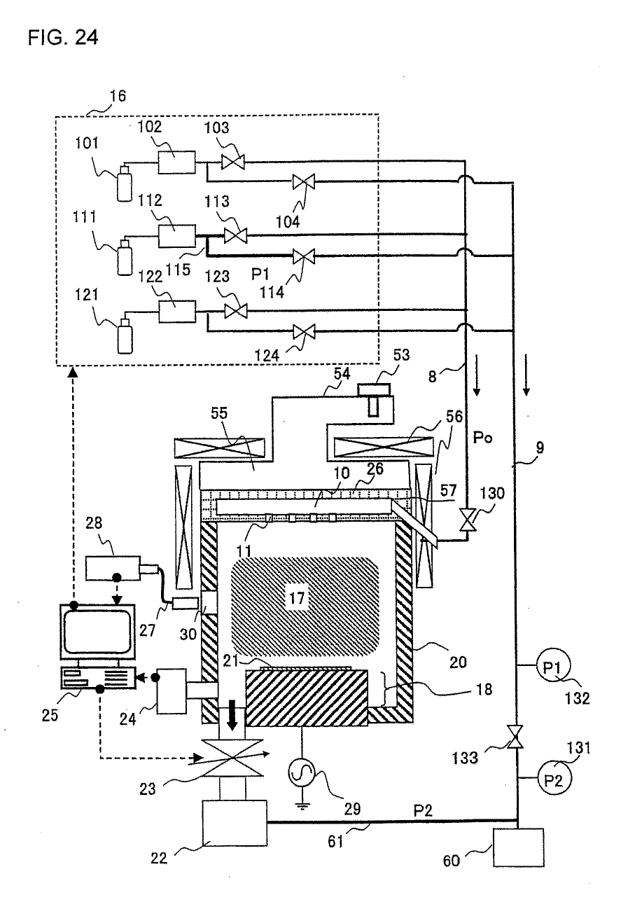

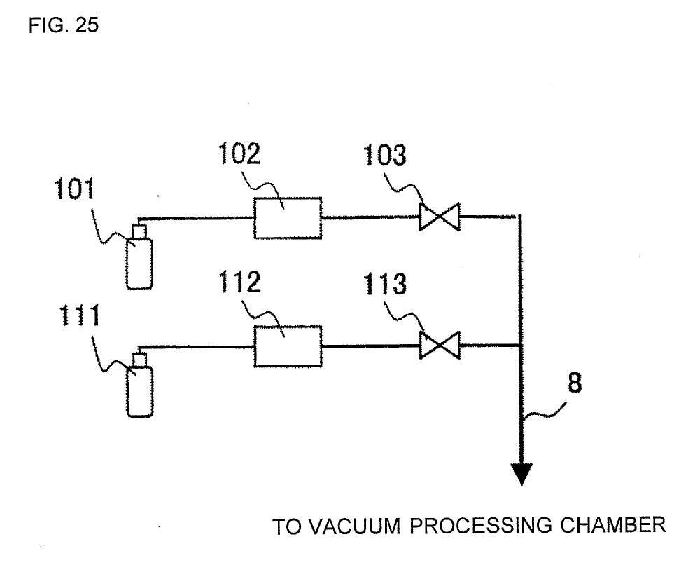

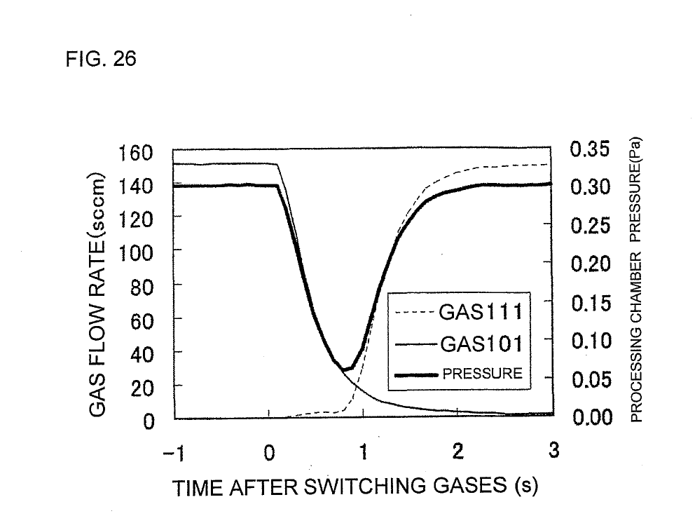

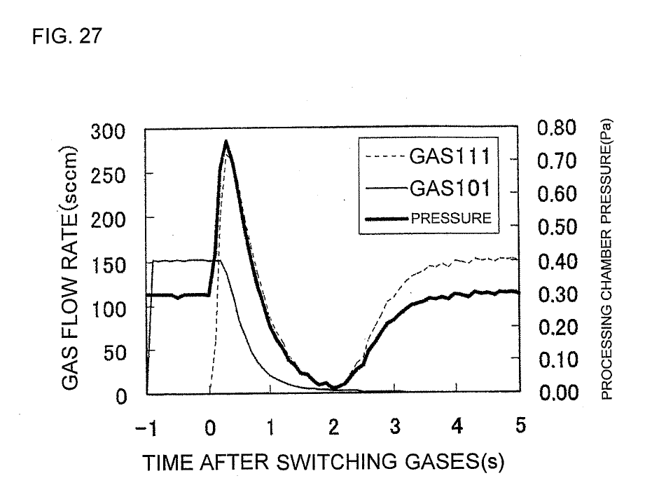

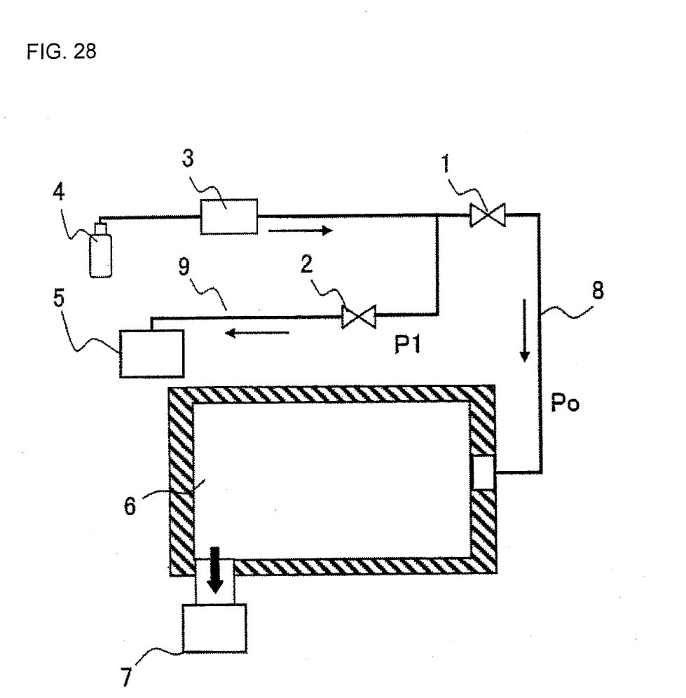

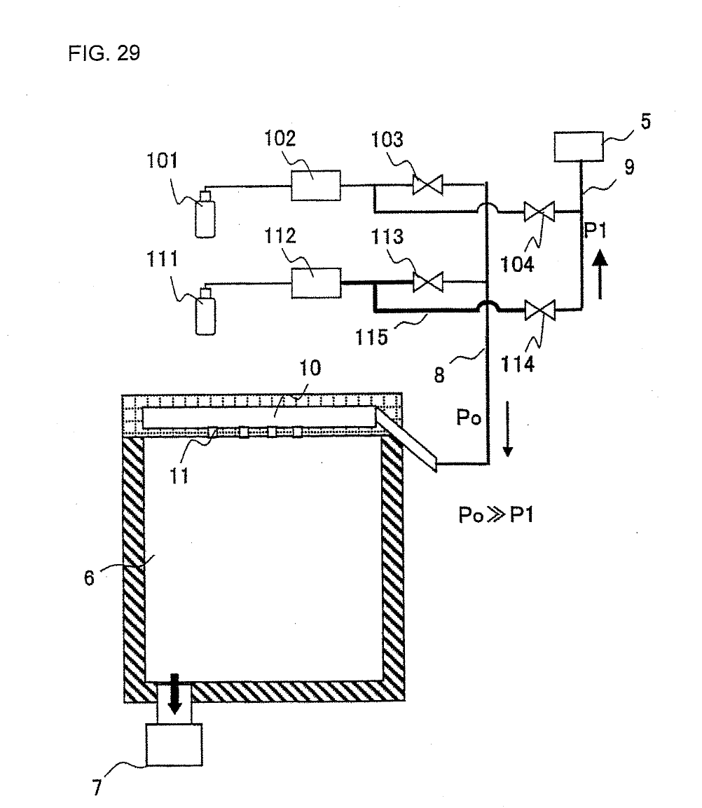

FIG. 24 illustrates another embodiment in which the exhaust pump 5 also serves as a back-pressure exhaust pump. According to the present invention, the gas supply unit is equipped with a gas line for a gas supply source 121 in addition to those of gas supply source 101 and gas supply source 111.

According further to the present embodiment, an exhaust gas line 9 is connected via a valve 133 to the polysilicon 61 communicating the turbo-molecular pump (exhaust means) 22 and the mask 60.

A case for switching from gas supply source 101 to gas supply source 111 using the present gas supply unit is described as an example. In the step where gas from gas supply source 101 is used, the valve 104 of the exhaust gas line of the gas supply source 101 is closed and the valves 103 and 130 attached to the processing gas line 8 are opened, so that a predetermined flow rate of gas is supplied from the MFC 102 to the vacuum processing chamber 20. The other valves are closed, and no gas from gas supply source 111 or gas supply source 121 is supplied. At a predetermined time “to” prior to the time for switching from gas supply source 101 to gas supply source 111, for example, 10 seconds prior thereto, the preparation for switching gases is started. The valve 114 is opened, and the flow rate of MFC 112 is set to the flow rate utilized in the subsequent step. Thereafter, the pressure P1 measured by the manometer 132 and the pressure P2 measured by the manometer 131 are monitored, and when P1 becomes higher than P2, the valve 133 is opened. This state is maintained until the flow rate of MFC 112 is stabilized, and then at the timing for switching from gas supply source 101 to gas supply source 111, the valve 113 is opened and the valves 114 and 103 are closed simultaneously. Thereafter, when P2 is sufficiently reduced, the valve 133 is closed.

According to the method of the present embodiment, it becomes possible to prevent exhaust from back-flowing into the exhaust gas line 9. Thus, the reaction products in the exhaust gas of the turbo-molecular pump are prevented from back-flowing via the exhaust gas line 9 into the vacuum processing chamber 20, so it becomes possible to prevent the occurrence of product defects caused by reaction products.

### Embodiment 6

With respect to the method of embodiment 5, while waiting for P1 to become higher than P2, the flow rate of MFC 112 is temporarily set to a higher value than the flow rate Qo used in the subsequent step. Thereafter, when P1 becomes greater than P2 and the valve 133 is opened, the flow rate is set to Qo. According to this arrangement, it becomes possible to reduce the time required for P1 to become greater than P2.

### Embodiment 7

With respect to the method of embodiment 5, while waiting for P1 to become higher than P2, the valve 124 is opened temporarily and the flow rate of MFC 122 is set to 1000 sccm. Thereafter, when P1 becomes greater than P2 and the valve 133 is opened, the flow rate is set to Qo. According to this arrangement, it becomes possible to reduce the time required for P1 to become greater than P2.

An Ar gas was used in the present embodiments, but equivalent effects can be achieved by utilizing a gas having low reactivity such as N₂ and other rare gases.

In addition, the plasma etching apparatus according to a first aspect of the present invention further characterizes in that the value of U in expression 1 determined by the volume Vo between the first valve and gas feed portion, the diameter d of the gas feed portion, the depth t of the hole and the number N of the holes is equal to or greater than 0.02 (Pa^{0.5}/s^{0.5}).

What is claimed is:

1. A plasma etching apparatus for subjecting a sample to an etching process by generating plasma from mixed gas, the apparatus comprising:
a vacuum processing chamber;
a gas pipe and a gas feed portion having a plurality of holes with an inner diameter smaller than an inner diameter of the gas pipe for supplying gas into the vacuum processing chamber;
a gas supply system for supplying a mixed gas composed of a plurality of gases via the gas pipe and the gas feed portion to the vacuum processing chamber; and
a first exhaust device connected to the vacuum processing chamber; wherein
the gas supply system is structured so that the gases are supplied via respective mass flow controllers to the vacuum processing chamber, the mass flow controllers each equipped with a first valve disposed between the vacuum processing chamber, a gas bypath pipe branched off from a portion between the mass flow controller and the first valve so as to be connected to a second exhaust device, and a second valve disposed on the gas bypath pipe, and wherein at least either each of the mass flow controllers, the first valves and the second valves are directly connected via an integrated gas system, or a variable conductance valve is disposed between the second exhaust device and the second valves.

2. A plasma etching apparatus for subjecting a sample to an etching process by generating plasma from mixed gas, the apparatus comprising:
a vacuum processing chamber;
a gas pipe and a gas feed portion having a plurality of holes with an inner diameter smaller than an inner diameter of the gas pipe for supplying gas into the vacuum processing chamber;
a gas supply system for supplying a mixed gas composed of a plurality of gases via the gas pipe and the gas feed portion to the vacuum processing chamber;
a first exhaust device connected to the vacuum processing chamber; and
a second exhaust device for evacuating exhaust gas from the first exhaust device;
wherein
the gas supply system is structured so that the gases are supplied via respective mass flow controllers to the vacuum processing chamber, the mass flow controllers each equipped with a first valve disposed between the vacuum processing chamber, a gas bypath pipe branched off from a portion between the mass flow controller and the first valve so as to be connected to a second exhaust device, and a second valve disposed on the gas bypath pipe, and wherein at least either each of the mass flow controllers, the first valves and the second valves are directly connected via an integrated gas system, or a variable conductance valve is disposed between the second exhaust device and the second valves.

3. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a value other than zero, and at a timing for switching conditions, opening the first valve of the gas line and closing the second valve of the gas line.

4. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a value other than zero, and at a timing for switching conditions, closing the second valve of the gas line at first, and thereafter, opening the first valve of the gas line.

5. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a value other than zero, and at the same time, controlling an opening of the variable conductance valve so that the value of a pressure P1 between the second valve and the variable conductance valve of the gas line is equal to or greater than a pressure Po between the first valve and the vacuum processing chamber of the gas line and equal to or smaller than 1.2 times the value of pressure Po, and at a timing for switching conditions, opening the first valve of the gas line and closing the second valve of the gas line.

6. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a value other than zero, and at a timing for switching conditions, opening the first valve of the gas line, closing the second valve of the gas line, and controlling the opening of the variable conductance valve so that a value of a pressure P1 between the second valve and the variable conductance valve of the gas line is set greater than a pressure P2 between the variable conductance valve and the second exhaust device.

7. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a flow rate value according to the subsequent condition, and at a timing for switching conditions, opening the first valve of the gas line and closing the second valve of the gas line.

8. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a flow rate value according to the subsequent condition, and at a timing for switching conditions, closing the second valve of the gas line at first, and thereafter, opening the first valve of the gas line.

9. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a flow rate value according to the subsequent condition, and at the same time, controlling an opening of the variable conductance valve so that the value of a pressure P1 between the second valve and the variable conductance valve of the gas line is equal to or greater than a pressure Po between the first valve and the vacuum processing chamber of the gas line and equal to or smaller than 1.2 times the value of pressure Po, and at a timing for switching conditions, opening the first valve of the gas line and closing the second valve of the gas line.

10. A plasma etching method for etching a sample by sequentially switching a plurality of gas conditions using the plasma etching apparatus according to claims 1 or 2, wherein
regarding a gas line that is not used in a current etching condition but used in a subsequent etching condition, the method comprises opening the second valve of the gas line in advance and setting the flow rate of the mass flow controller to a flow rate value according to the subsequent condition, and at a timing for switching conditions, opening the first valve of the gas line, closing the second valve of the gas line, and controlling the opening of the variable conductance valve so that a value of a pressure P1 between the second valve and the variable conductance valve of the gas line is set greater than a pressure P2 between the variable conductance valve and the second exhaust device of the gas line.

11. A plasma etching method for etching a sample by sequentially switching a plurality of gas conditions using the plasma etching apparatus according to claims 1 or 2, wherein
regarding a gas line that is not used in a current etching condition but used in a subsequent etching condition, switching of gases is performed by opening the second valve of the gas line in advance and setting the flow rate of the mass flow controller to a value other than zero, and at a timing for switching conditions, opening the first valve of the gas line and closing the second valve of the gas line; and a total gas flow rate immediately after switching conditions is set to an intermediate value between that of the current etching condition and that of the subsequent etching condition.

12. A plasma etching method for etching a sample by sequentially switching a plurality of gas conditions using the plasma etching apparatus according to claims 1 or 2, wherein
regarding a gas line that is not used in a current etching condition but used in a subsequent etching condition, switching of gases is performed by opening the second valve of the gas line in advance and setting the flow rate of the mass flow controller to a value other than zero, and at a timing for switching conditions, closing the second valve of the gas line at first, and thereafter, opening the first valve of the gas line; and a total gas flow rate immediately after switching conditions is set to an intermediate value between that of the current etching condition and that of the subsequent etching condition.

13. A plasma etching method for etching a sample by sequentially switching a plurality of gas conditions using the plasma etching apparatus according to claims 1 or 2, wherein
regarding a gas line that is not used in a current etching condition but used in a subsequent etching condition, switching of gases is performed by opening the second valve of the gas line in advance and setting the flow rate of the mass flow controller to a value other than zero, and at the same time, controlling an opening of the variable conductance valve so that the value of a pressure P1 between the second valve and the variable conductance valve of the gas line is equal to or greater than a pressure Po between the first valve and the vacuum processing chamber of the gas line and equal to or smaller than 1.2 times the value of pressure Po, and at a timing for switching conditions, opening the first valve of the gas line and closing the second valve of the gas line; and a total gas flow rate immediately after switching conditions is set to an intermediate value between that of the current etching condition and that of the subsequent etching condition.

14. A plasma etching method for etching a sample by sequentially switching a plurality of gas conditions using the plasma etching apparatus according to claims 1 or 2, wherein
regarding a gas line that is not used in a current etching condition but used in a subsequent etching condition, switching of gases is performed by opening the second valve of the gas line in advance and setting the flow rate of the mass flow controller to a value other than zero, and at a timing for switching conditions, opening the first valve of the gas line and closing the second valve of the gas line; and a total gas flow rate immediately after switching conditions is set to a value greater than that of the subsequent etching condition if the pressure according to the subsequent etching condition is higher than the current etching condition, and set to a value smaller than that of the subsequent etching condition if the pressure according to the subsequent etching condition is lower than the current etching condition.

15. A plasma etching method for etching a sample by sequentially switching a plurality of gas conditions using the plasma etching apparatus according to claims 1 or 2, wherein
regarding a gas line that is not used in a current etching condition but used in a subsequent etching condition, switching of gases is performed by opening the second valve of the gas line in advance and setting the flow rate of the mass flow controller to a value other than zero, and at a timing for switching conditions, closing the second valve of the gas line at first, and thereafter, opening the first valve of the gas line; and a total gas flow rate immediately after switching conditions is set to a value greater than that of the subsequent etching condition if the pressure according to the subsequent etching condition is higher than the current etching condition, and set to a value smaller than that of the subsequent etching condition if the pressure according to the subsequent etching condition is lower than the current etching condition.

16. A plasma etching method for etching a sample by sequentially switching a plurality of gas conditions using the plasma etching apparatus according to claims 1 or 2, wherein
regarding a gas line that is not used in a current etching condition but used in a subsequent etching condition, switching of gases is performed by opening the second valve of the gas line in advance and setting the flow rate of the mass flow controller to a value other than zero, and at the same time, controlling an opening of the variable conductance valve so that the value of a pressure P1 between the second valve and the variable conductance valve of the gas line is equal to or greater than a pressure Po between the first valve and the vacuum processing chamber of the gas line and equal to or smaller than 1.2 times the value of pressure Po, and at a timing for switching conditions, opening the first valve of the gas line and closing the second valve of the gas line; and a total gas flow rate immediately after switching conditions is set to a value greater than that of the subsequent etching condition if the pressure according to the subsequent etching condition is higher than the current etching condition, and set to a value smaller than that of the subsequent etching condition if the pressure according to the subsequent etching condition is lower than the current etching condition.

17. A plasma etching apparatus for subjecting a sample to an etching process by generating plasma from mixed gas, the apparatus comprising:
a vacuum processing chamber;
a gas pipe and a gas feed portion having a plurality of holes with an inner diameter smaller than an inner diameter of the gas pipe for supplying gas into the vacuum processing chamber;
a gas supply system for supplying a mixed gas composed of a plurality of gases via the gas pipe and the gas feed portion to the vacuum processing chamber;
a first exhaust device connected to the vacuum processing chamber; and
a second exhaust device for evacuating exhaust gas from the first exhaust device;
wherein
the gas supply system is structured so that the gases are supplied via respective mass flow controllers to the vacuum processing chamber, the mass flow controllers each equipped with a first valve disposed between the vacuum processing chamber, a gas bypath pipe branched off from a portion between the mass flow controller and the first valve so as to be connected to a second exhaust device, a second valve disposed on the gas bypath pipe, a third valve disposed between the second exhaust device and the second valve, a first manometer for measuring a pressure between the third valve and the second valve, and a second manometer for measuring a pressure between the third valve and the second exhaust device.

18. A plasma etching method for etching a sample by sequentially switching a plurality of gas conditions using the plasma etching apparatus according to claim 17, wherein
regarding a gas line that is not used in a current etching condition but used in a subsequent etching condition, the method comprises opening the second valve of the gas line in advance with the third valve closed, and setting the flow rate of the mass flow controller to a value other than zero, and thereafter, when the pressure of the first manometer becomes higher than that of the second manometer, opening the third valve, then at a timing for switching conditions, opening the first valve of the gas line and closing the second valve of the gas line.
